(19) United States
(12) Patent Application Publication
(10) Pub. No.: US 2004/0082167 A1
(43) Pub. Date: Apr. 29, 2004

(54) Methods of forming aluminum structures in microelectronic articles and articles fabricated thereby

(76) Inventors: Jung-Hun Seo, Gangwon-do (KR); Gil-Heyun Choi, Gyeonggi-do (KR); Ju-Young Yun, Seoul (KR); Byung-Hee Kim, Seoul (KR); Seung-Gil Yang, Gyeonggi-do (KR)

Correspondence Address: MYERS BIGEL SIBLEY & SAJOVEC, PO BOX 37428, RALEIGH, NC, 27627, US

(21) Appl. No.: 10/620,995

(22) Filed: Jul. 16, 2003

(30) Foreign Application Priority Data
Aug. 26, 2002 (KR) 2002-50491

(51) Int. Cl. H01L 21/44; H01L 21/302; H01L 21/461

(52) U.S. Cl. 438/658; 438/681; 438/688

(57) ABSTRACT

A recess is formed in a microelectronic substrate, and then a metal-containing layer is formed that conforms to an inner surface of the recess and to a surface of the substrate adjacent the recess. A carbon concentration in a portion of the metal-containing layer on the surface of the substrate adjacent the recess is decreased in comparison to a portion of the metal-containing layer within the recess, e.g., using a plasma treatment that has a greater effect on the surface outside of the recess. Aluminum is then deposited on the metal-containing layer to form an aluminum layer that conforms to the inner surface of the recess and to the surface of the substrate adjacent the recess. Preferably, the carbon concentration in the portion of the metal-containing layer within the recess is sufficiently great to cause aluminum to deposited at a greater rate on the portion of the metal-containing layer within the recess.

### RELATED APPLICATION

This application claims priority from Korean Patent Application No. 2002-50491 filed on Aug. 26, 2002 in the Korean Intellectual Property Office, the disclosure of which is incorporated herein in its entirety by reference.

### FIELD OF THE INVENTION

The present invention relates to forming conductive structures, such as contacts, in microelectronic articles, such as integrated circuit (semiconductor) devices. More particularly, the present invention relates to forming aluminum structures in microelectronic articles.

### BACKGROUND OF THE INVENTION

In a typical microelectronic (e.g., semiconductor or integrated circuit) device, contacts that electrically connect between interconnections, between an interconnection and an impurity-doped region, or between an interconnection and a transistor, are typically composed of conductive materials. As metal interconnection structures have become more highly integrated and multi-layered, aspect ratios of the contact holes in the devices have generally increased. A conventional method for forming aluminum contacts, such as chemical vapor deposition (CVD) or sputtering of aluminum, may generate void defects in small size contact holes and/or a bad step coverage where a contact hole has a high step difference.

FIGS. 1A and 1B are cross-sectional views of a conventional technique for forming an aluminum contact. A bottom layer 3 is formed over a semiconductor substrate 1, and a conductive region 5 is formed on the bottom layer 3. An interlayer dielectric layer 7 is formed to cover the conductive region 5 and patterned to form a contact hole exposing the conductive region 5. An ohmic metal layer 9 is formed in the contact hole 8. A relatively thin metal layer 10 is formed on the ohmic metal layer 9.

An aluminum layer 11 is then formed on the metal layer 10 using a sputtering or CVD method. The aluminum layer 11 is thickly deposited at the entrance of the contact hole 8, but the aluminum may sparsely deposit in the contact hole 8. Therefore, the aluminum may form discontinuous islands in the contact hole 8. If the aluminum continues to be deposited, the entrance of the contact hole may become plugged and a void V may form, as shown in FIG. 1B. It may be difficult to fill this void, even if a reflow process is performed as a subsequent step. This may cause reliability problems.

### SUMMARY OF THE INVENTION

According to some embodiments of the present invention, an aluminum structure is formed in a microelectronic article, such as an integrated circuit. A recess, such as a contact hole, via hole, trench, groove or step, is formed in a microelectronic substrate. A metal-containing layer is formed conforming to a surface of the recess and to an adjacent surface of the substrate. The substrate having the metal-containing layer thereon is then plasma treated. Aluminum is then deposited on the metal-containing layer at a temperature of about 160° C. or less to form an aluminum layer thereon. The metal-containing layer may be formed by metal organic chemical vapor deposition (MOCVD). The metal-containing layer may be barrier metal layer including, for example, titanium (Ti) and/or tantalum (Ta). For example, the metal-containing layer may include at least one material selected from a group consisting of titanium nitride (TiN), tantalum nitride (TaN), titanium silicon nitride (TiSiN) and tantalum silicon nitride (TaSiN).

The aluminum may be deposited on the metal-containing layer by chemical vapor deposition (CVD) using a methylpyrrolidine alane (MPA) source gas. Plasma treating the substrate may include plasma treating using at least one gas selected from a group consisting of argon (Ar), hydrogen (H₂), nitrogen (N₂), oxygen (O₂), nitrous oxide (N₂O) and ammonia (NH₃). The plasma treating may occur at a pressure in a range from about 1 Torr to about 6 Torr and/or at a power level in a range from about 600 W to about 1,000 W. The formation of the metal-containing layer may be preceded by forming an ohmic layer conforming to the interior surface of the recess and to the adjacent surface of the insulating layer, and the metal-containing layer may be formed on the ohmic layer. The ohmic layer may include at least one of titanium (Ti) or tantalum (Ta).

In further embodiments of the present invention, a first metal-containing layer is formed and plasma treated, and then aluminum is deposited on the first metal-containing layer to form a first aluminum layer thereon. A second metal-containing layer is then formed on the first aluminum layer and plasma treated. Aluminum is then deposited on the second metal-containing layer at a temperature of about 160° C. or less to form a second aluminum layer thereon.

According to still further embodiments of the present invention, a recess is formed in a microelectronic substrate, and then a metal-containing layer is formed that conforms to an inner surface of the recess and to a surface of the substrate adjacent the recess. A carbon concentration in a portion of the metal-containing layer on the surface of the substrate adjacent the recess is decreased in comparison to a portion of the metal-containing layer within the recess, e.g., using a plasma treatment that has a greater effect on the surface outside of the recess. Aluminum is then deposited on the metal-containing layer to form an aluminum layer that conforms to the inner surface of the recess and to the surface of the substrate adjacent the recess. Preferably, decreasing a carbon concentration includes creating a difference in carbon concentration between the portion of the metal-containing layer on the surface of the substrate adjacent the recess and the portion of the metal-containing layer within the recess sufficient to cause aluminum to deposited at a greater rate on the portion of the metal-containing layer within the recess than on the portion of the metal-containing layer on the surface of the substrate adjacent the recess.

According to still further aspects of the present invention, a microelectronic article of manufacture includes a substrate having a recess therein, and a metal-containing layer on the substrate that conforms to an inner surface of the recess and to a surface of the substrate adjacent the recess. The metal-containing layer has a substantially higher concentration of carbon in a portion of the metal-containing layer in the recess than in a portion of the metal-containing layer on the surface of the substrate adjacent the recess. More particularly, the concentration of carbon in the portion of the metal-containing layer in the recess is sufficiently higher that the carbon concentration in the portion of the metal-containing layer on the surface of the substrate adjacent the recess to cause aluminum to deposit more rapidly on the portion of the metal-containing layer in the recess that on the portion of the metal-containing layer on the surface of the substrate adjacent the recess in an CVD process using an MPA source gas.

### BRIEF DESCRIPTION OF THE DRAWINGS

FIGS. 1A and 1B are cross-sectional views of fabrication products illustrating operations for forming an aluminum contact according to a conventional method.

FIGS. 2A through 2E are cross-sectional views of fabrication products illustrating exemplary operations for forming an aluminum contact according to some embodiments of the present invention.

FIG. 2F is a cross-sectional view of a fabrication product illustrating exemplary operations for forming an aluminum contact according to other embodiments of the present invention.

FIG. 3 is a graph comparing thicknesses of aluminum layers deposited according to embodiments of the present invention and according to a conventional technique.

FIG. 4 is a tunneling electron microscope (TEM) photo showing a cross-section of aluminum contacts formed according to some embodiments of the present invention.

FIGS. 5A and 5B are scanning electron microscope (SEM) photos of aluminum contacts formed according to embodiments of the present invention and according to a conventional technique, respectively.

FIGS. 6A and 6B are SEM photos of aluminum contacts formed according to further embodiments of the present invention and according to a conventional technique, respectively.

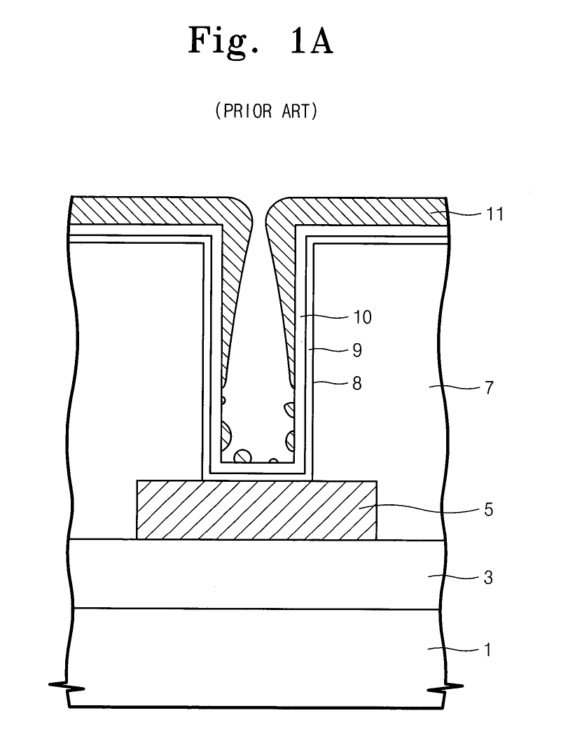

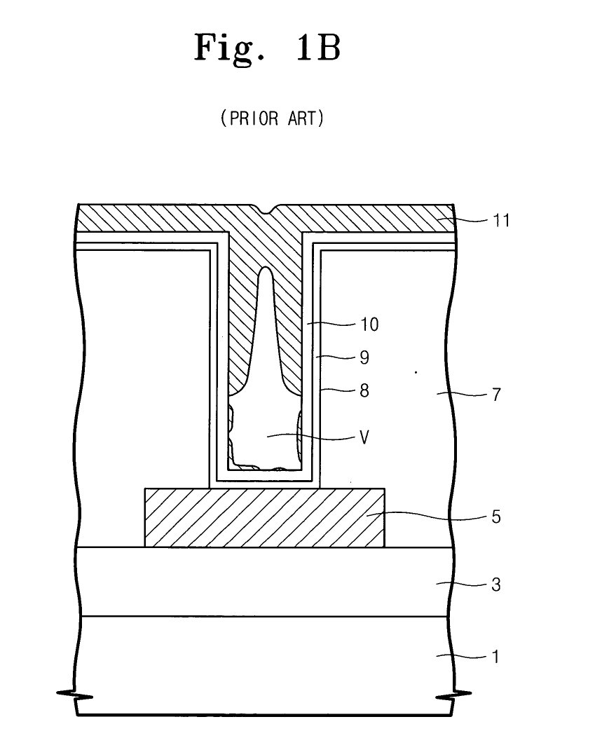

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

In the drawings, the thickness of layers and regions are exaggerated for clarity. It will be understood that when an element such as a layer, region or substrate is referred to as being “on” another element, it can be directly on the other element or intervening elements may also be present. Furthermore, relative terms, such as “beneath”, may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as “below” other elements would then be oriented “above” the other elements. The exemplary term “below”, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout.

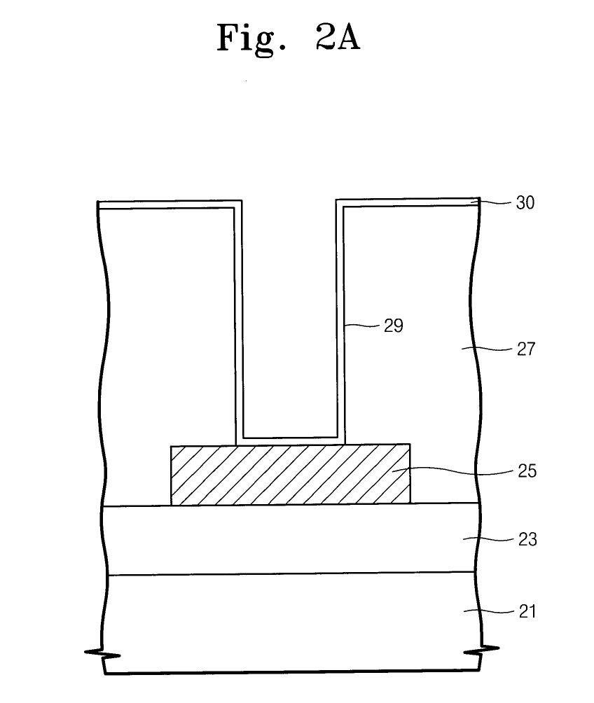

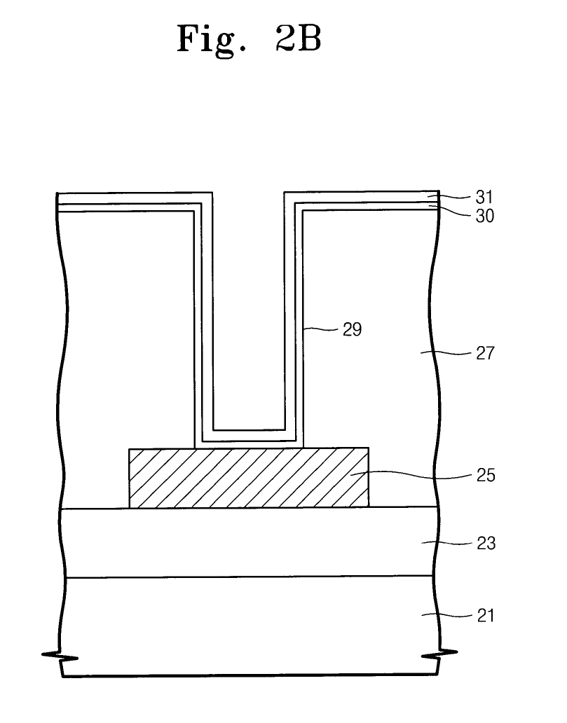

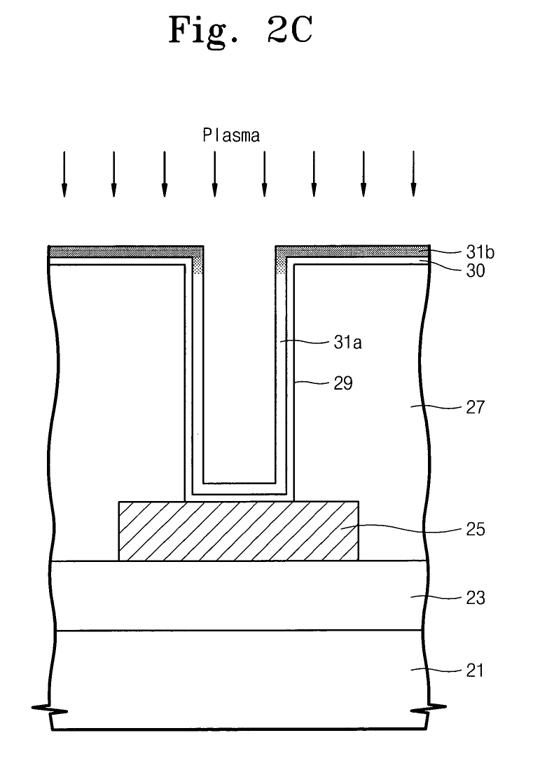

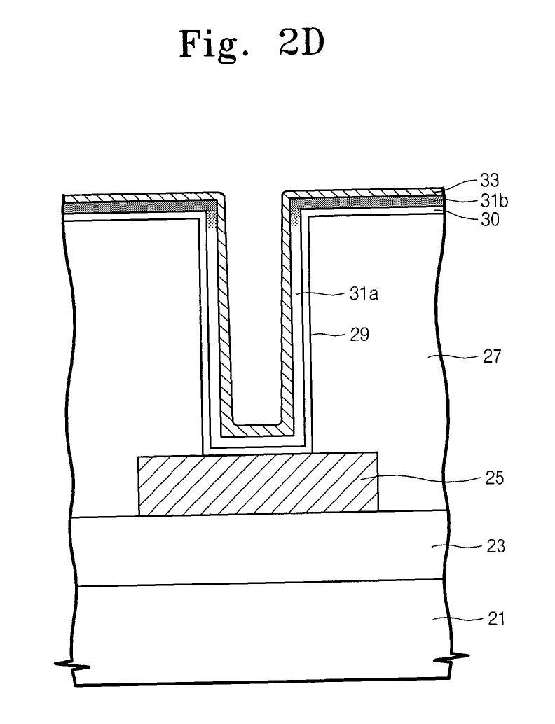

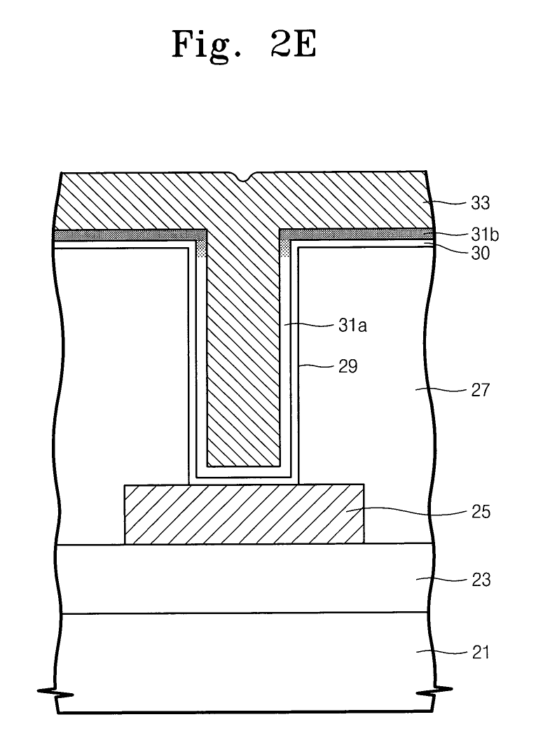

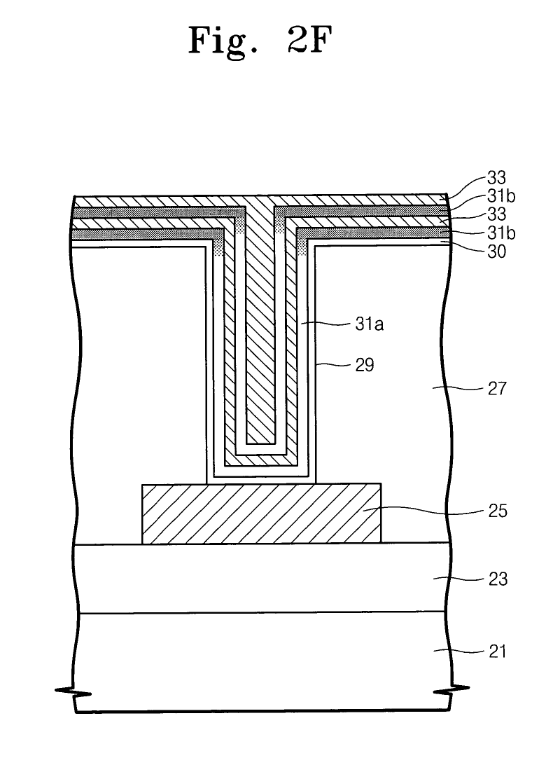

FIGS. 2A through 2E are cross-sectional views illustrating formation of an aluminum contact according to some embodiments of the present invention.

Referring to FIG. 2A, a bottom layer 23 is formed on a semiconductor substrate 21, and a conductive region 25 is formed on the bottom layer 23. The bottom layer 23 may be, for example, an oxide layer, and the conductive region 25 may be, for example, a bottom interconnection or a gate electrode. In other embodiments, the bottom layer 23 may be not present and the conductive region 25 may be an impurity-doped region in the substrate 21.

An interlayer dielectric layer 27 is formed on the conductive region 25, and patterned to form a contact hole 29 exposing the conductive region 25. The contact hole 29 is shown for illustrative purposes, i.e., as an example of an integrated circuit feature exhibiting a step difference with respect to adjacent structures. It will be apparent to those skilled in the art that the present invention may be applied to various types of recesses, such as a hole, groove, via hole, trench, contact hole formed in a dual damascene process, or an interconnection groove. An ohmic metal layer 30 is formed on the semiconductor substrate 21 having the contact hole 29. The ohmic metal layer 30 may be formed of, for example, titanium or tantalum.

Referring to FIG. 2B, a thin metal layer 31 is formed on the ohmic metal layer 30. The metal layer 31 may be formed using, for example, metal organic chemical vapor deposition (MOCVD). The metal layer 31 may be formed of a material selected from a group consisting of titanium nitride (TiN), tantalum nitride (TaN), titanium silicon nitride (TiSiN) and tantalum silicon nitride (TaSiN), which may be provided by metal organic sources such as tetrakis-dimethyl-amino-titanium (TDMAT).

Referring to FIG. 2C, the metal layer 31 is then plasma-treated. The portion of the metal layer 31 on the top of the interlayer dielectric layer 27 is relatively more affected by the plasma treatment than the portion of the metal layer 31 in the contact hole 29. According to some embodiments of the present invention, it is preferable that these portions be selectively and differentially plasma-treated. In order to selectively and differentially plasma treat these portions, it can be advantageous to use relatively high power and/or short treatment time in the plasma treatment. It can also be advantageous to use a relatively high process pressure and/or for the contact hole 29 to have a relatively high aspect ratio. In some preferred embodiments, the plasma treatment is performed at a power level of 600˜1000 W and at a pressure of 1˜6 Torr for about 60 seconds. The plasma treatment may be carried out by using at least one gas selected from a group consisting of argon (Ar), hydrogen (H₂), nitrogen (N₂), oxygen (O₂), nitrous oxide (N₂O) and ammonia (NH₃).

If the metal layer is formed from metal organic sources, the metal layer 31 may contain many carbon atoms. As the metal layer 31 is plasma treated, many of the carbon atoms contained in a portion 31b may be eliminated, and a portion of titanium or tantalum thereby increased. Thus, the metal layer 31 can be changed to a metal layer having a portion 31b containing fewer carbon atoms and a portion 31a containing more carbon atoms.

Referring to FIG. 2D, an aluminum layer 33 is formed on the plasma-treated metal layer, preferably at a temperature of 160° C. or less. When the aluminum layer 33 is deposited at a low temperature of 160° C. or less, a surface of the deposited aluminum layer 33 can have a desired smoothness and relatively high density. The aluminum layer 33 may be formed by using CVD with a methylpyrrolidine alane (MPA) source gas. Conventional source gases for forming aluminum layers include dimethyl ethyl amine alane (DMEAA), dimethyl aluminum hydride (DMAH) and trimethylamine alane (TMAA). However, MPA, as used in embodiments of the present invention, can exhibit a desirable stability and low deposition rate in comparison these conventional source gases, so that MPA is preferred in some embodiments.

The aluminum layer 33 tends to form more thickly on the metal layer portion 31a in the contact hole 29, which may be less affected by the plasma-treatment than on the metal layer portion 31b outside of and/or at the edges of the contact hole 29. In particular, the aluminum layer 33 may deposit more on the metal layer portion 31a that contains lower Ti or Ta content due to the lesser plasma treatment.

This may be explained as follows. In order to deposit an aluminum layer 33, a source gas that contains a combination of aluminum atoms and ligands may be supplied to form a preliminary aluminum layer on the metal layer 31. The ligands can be removed from the preliminary aluminum layer to form an aluminum layer that contains only pure aluminum. However, the Ti or Ta contained in the metal layer 31 has a relatively strong bonding strength with the ligands. The strong bonding of the Ti or Ta can prevent the ligands from being removed from the preliminary aluminum layer. Thus, as the amount of Ti or Ta in the metal layer 31 is increased, aluminum is less easily deposited. This is why the aluminum layer 33 may be more thickly formed on the metal layer portion 31a that is less plasma treated.

Referring to FIG. 2E, the aluminum layer 33 may be deposited using a CVD method to fill the contact hole 29. Alternatively, after forming a seed aluminum layer (not shown) by using a CVD method, the aluminum layer 33 can continue to be formed by using a physical vapor deposition (PVD) sputtering method to fill the contact hole 29. Subsequently, a reflow process may be performed.

FIG. 2F is a cross-sectional view illustrating operations for forming an aluminum contact according to further embodiments of the present invention. In these embodiments, processes of FIGS. 2B, 2C and 2D are repeated at least one additional time in the state of FIG. 2B of the first embodiment. In other words, a first step of forming the metal layer 31 as in FIG. 2B, a second step of selectively plasma-treating the metal layer 31 as in FIG. 2C, and a third step of stacking an aluminum layer 33 as in FIG. 2D are repeatedly performed to fill the contact hole 29 as illustrated in FIG. 2F. Kinds of layers and process conditions of the present embodiment are the same with those of the first embodiment.

### EXPERIMENTAL EXAMPLE 1

The present experimental example was performed in order to judge whether the MPA is appropriate for the source gas of an aluminum layer and in order to know a proper deposition temperature of the aluminum layer. A plurality of bare silicon substrates were prepared. Titanium nitride (TiN) layers were formed on the substrates using a MOCVD method.

The substrates having the TiN layers are classified into four groups as illustrated in Table 1.

TABLE 1

| | Group 1 | Group 2 | Group 3 | Group 4 |
|---|---|---|---|---|
| Plasma treatment | Yes | No | Yes | No |
| Source gas | MPA | MPA | DMEAA | DMEAA |

Groups 1 and 3 received plasma treatment for the TiN layer, but groups 2 and 4 did not. Plasma treatment conditions for groups 1 and 3 are recorded in Table 2:

TABLE 2

| | | | Reactor | Reactor | |
|---|---|---|---|---|---|
| Plasma | | Gas flow | chamber | chamber | |
| gas | Power | rate | temperature | pressure | Time |
| Ar | 400 W | 1500 sccm | 650° C. | 5.0 Torr | 60 seconds |

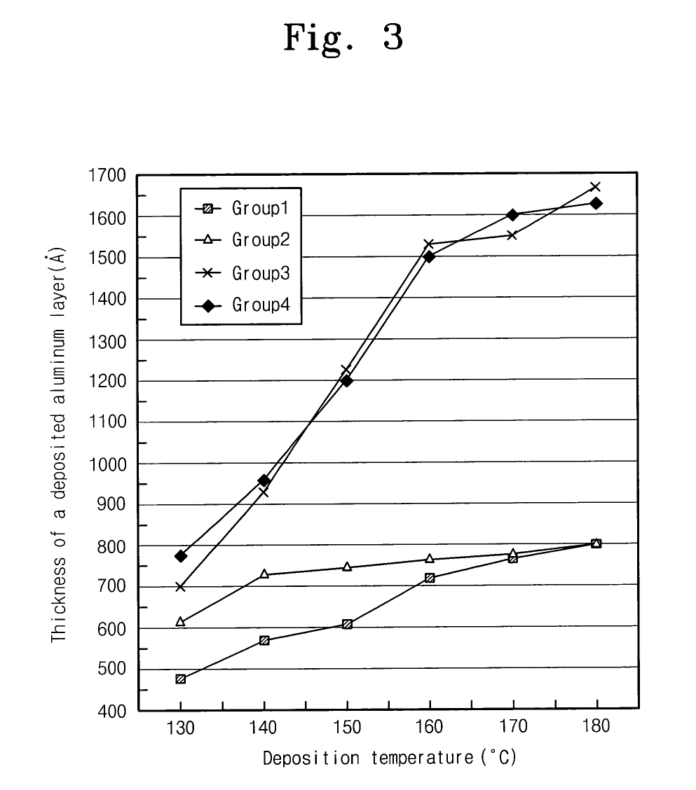

Aluminum layers were deposited on the substrates. MPA was used for the source gas in groups 1 and 2, but DMEAA was used as the source gas for groups 3 and 4. The aluminum layers were deposited over 60 second intervals. Relationships between thickness of the aluminum layers and deposition temperatures for the groups are shown in FIG. 3.

Referring to FIG. 3, aluminum layers in groups 1 and 2 using MPA are thinner than those in groups 3 and 4 using DMEAA. In other words, the aluminum layers formed using MPA as a source gas were thinner in comparison with layers formed using DMEAA. It is believed that this is because the molecular structure of MPA is more stable than that of DMEAA. At temperatures of 160° C. or lower, there is a difference in the thickness of deposited aluminum layers between groups 1 and 2. However, there is almost no difference in thickness between groups 3 and 4 through the temperature range from 130 to 180° C. According to some embodiments of the present invention, it is desirable to use a source gas showing a differential deposition rate based on the amount of plasma treatment. Therefore, MPA can be a good aluminum source gas for embodiments of the present invention.

### EXPERIMENTAL EXAMPLE 2

In order to illustrate a differential deposition rate based on the degree of plasma treatment, first and second bare silicon substrates were prepared. TiN layers were formed on the first and second substrates using an MOCVD method. A plasma treatment process was performed on the TiN layer of the first substrate using Ar gas, while no plasma treatment process was performed on the TiN layer of the second substrate. The plasma treatment process using the Ar gas was performed under the conditions shown in Table 2.

Aluminum layers were formed on the first and second substrates using a CVD method with an MPA source gas. The aluminum layers on the first and second substrates were formed at a temperature of 140° C. for a period of 60 seconds. As shown in Table 3, the aluminum layer formed on the second substrate was thicker than that formed the first substrate. In particular, the thickness of the aluminum layer formed on the second, plasma-treated substrate was 795 Å, while the aluminum layer formed on the non-plasma-treated substrate had a thickness of 665 Å.

TABLE 3

| | Thickness of a |
|---|---|
| | deposited aluminum layer |
| First substrate plasma-treated | 665 Å |
| Second substrate non-plasma-treated | 795 Å |

### EXPERIMENTAL EXAMPLE 3

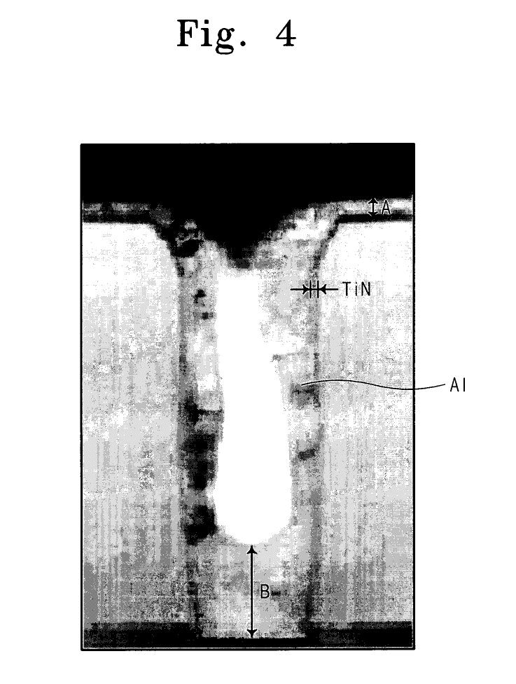

FIG. 4 illustrates a TEM photo of showing cross-sectional views of an aluminum contact formed according to further embodiments of the present invention. An oxide interlayer dielectric layer was formed on a substrate using a CVD method. The interlayer dielectric layer was patterned to form a contact hole having an aspect ratio of 3.5. The depth and diameter of the contact hole were 770 nm and 220 nm, respectively. A conformal TiN layer was formed to a thickness of 50 Å on the surface of the substrate, including in the contact hole. The TiN layer was formed using a MOCVD method with a TDMAT source gas. The TiN layer was plasma-treated. The plasma treatment was performed under conditions of shown in Table 4.

TABLE 4

| Plasma | | Gas flow | Reactor | Reactor | |
|---|---|---|---|---|---|
| gas | Power | rate | temperature | pressure | Time |
| Ar | 800 W | 1500 sccm | 650° C. | 5.0 Torr | 20 seconds |

An aluminum layer was formed on the plasma-treated TiN layer using a CVD process at a temperature of 140° C. with an MPA source gas for a duration that, if the aluminum layer had been formed on a flat bare substrate, would produce an aluminum layer with a thickness of 600 Å. As shown in FIG. 4, the aluminum layer was formed more thickly at a location “B” inside the contact hole in comparison with a location “A” outside the contact hole. Also, the aluminum layer was continuous, i.e., it included no “islands.”

### EXPERIMENTAL EXAMPLE 4

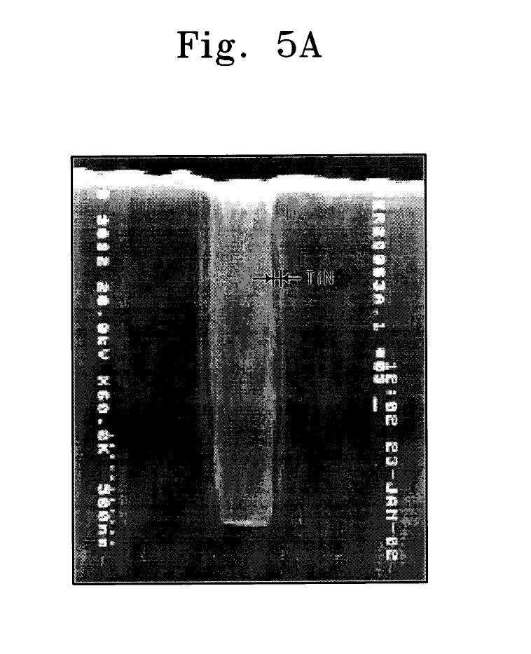

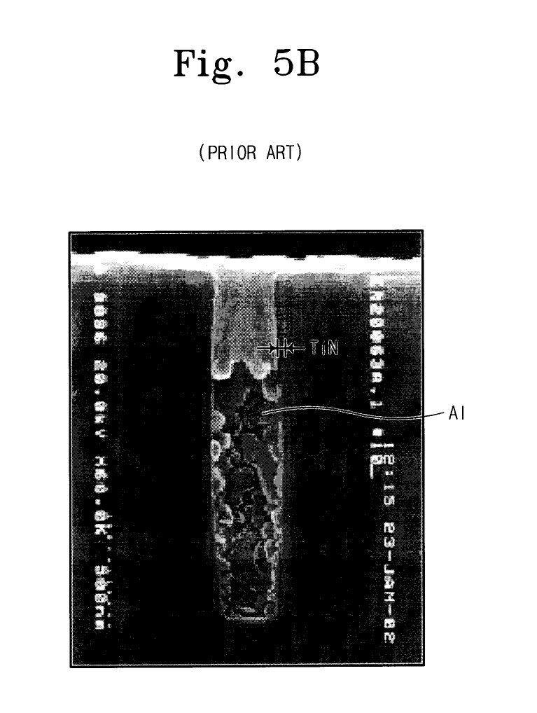

FIGS. 5A and 5B illustrate SEM photos of aluminum contacts formed according to some embodiments of the present invention and using conventional techniques, respectively. Two semiconductor substrates were prepared. A contact hole having a width of 300 nm and an aspect ratio of 5.0 was formed on each semiconductor substrate. A TiN layer was conformally formed on each semiconductor substrate, including inside the contact hole. The TiN layers were formed using an MOCVD method with a TDMAT source gas.

The semiconductor substrate of FIG. 5A was exposed to plasma, but the semiconductor substrate of FIG. 5B was not. The plasma was generated under the conditions shown in Table 4. An aluminum layer was formed on each semiconductor substrate using a CVD method with an MPA source gas at a process temperature of 140° C. for a duration that would form an aluminum layer with a thickness of 600 Å on a flat bare substrate.

The substrates were cross-sectioned at the contact holes, and cross-sectional photos of the cut substrates were taken by using a scanning electron microscope (SEM) to get FIGS. 5A and 5B. In FIG. 5A, the aluminum layer is not shown because the continuous aluminum layer was inadvertently removed when the contact hole was cut. Thus, FIG. 5A shows a contact hole where the aluminum layer was totally removed. However, in FIG. 5B, it is possible to see islands of aluminum that is discontinuously formed in the contact hole.

### EXPERIMENTAL EXAMPLE 5

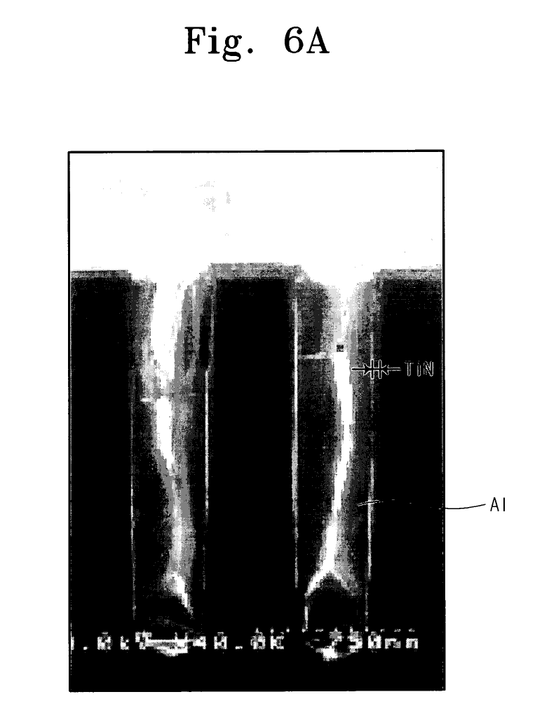

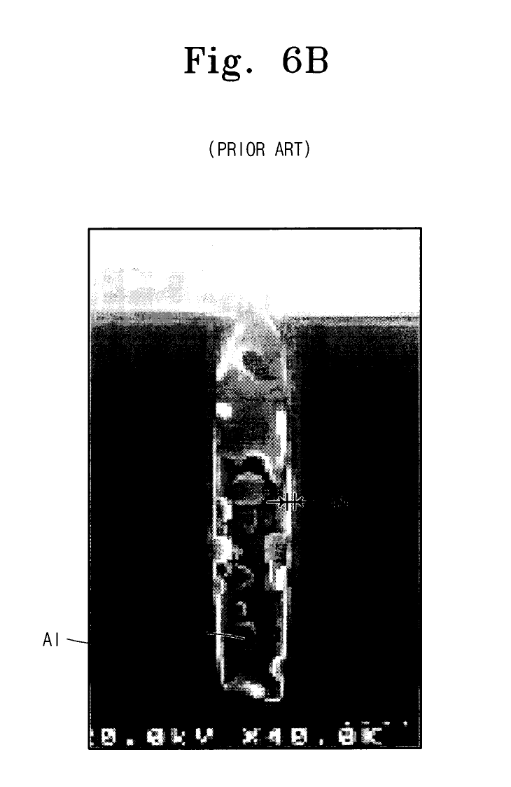

This experimental example was carried out in order to determine whether a contact hole with islands of a aluminum like FIG. 5B could be filled by a reflow process. FIGS. 6A and 6B illustrate SEM photos of aluminum contacts which are formed according to embodiments of the present invention and by a conventional technology, respectively. Like the fourth experimental example, two semiconductor substrates were prepared. A contact hole having a width of 300 nm and an aspect ratio of 5.0 was formed on each semiconductor substrate. A TiN layer was conformally formed on each semiconductor substrate including inside the contact holes. A TiN layer was then formed on each substrate using an MOCVD method with a TDMAT source gas. The semiconductor substrate of FIG. 6A was then exposed to plasma, while the semiconductor substrate of FIG. 6B was not. The plasma was generated under the conditions shown in Table 4.

An aluminum layer was then formed on each semiconductor substrate using a CVD method with an MPA source gas at a process temperature of 140° C. for a duration that would be formed an aluminum layer with a thickness of 600 Å on a flat bare substrate. An additional aluminum layer was then formed on each semiconductor substrate to a thickness of 7,400 Å by using a PVD method to fill the contact holes. In order to remove a void, such as that shown in FIG. 5B, a reflow process was performed on each semiconductor substrate at a temperature of 585° C. for 3 minutes. Each of the substrates was then cross-sectioned at the contact holes, and cross-sectional photos thereof were taken using a SEM to produce FIGS. 6A and 6B. FIG. 6A shows a contact hole that is fully filled with aluminum, without a void. However, FIG. 6B shows a void and islands of aluminum at a lower portion of the contact hole.

Thus, it was shown that a void may remain after a reflow process if an aluminum layer is discontinuously formed in a contact hole. Similar experiments were performed for contact holes having an aspect ratio of 6.1, and produced similar results as fourth and fifth experimental examples shown above.

According to some embodiments of the present invention, formation of an aluminum contact includes using a differential plasma treatment before aluminum deposition to avoid forming a void in a contact hole. This can improve the reliability of a metal interconnection using such a contact. In addition, because an aluminum layer for forming an aluminum contact can be formed at a temperature of 160° C. or less by supplying MPA as a source gas according to further embodiments of the present invention, a surface of the aluminum layer can be made smooth and a density of the aluminum layer can be increased.

In the drawings and specification, there have been disclosed typical embodiments of the invention and, although specific terms are employed, they are used in a generic and descriptive sense only and not for purpose of limitation, the scope of the invention being set forth in the following claims.

What is claimed is:

1. A method of forming an aluminum structure in a microelectronic article, the method comprising:
forming a recess in a microelectronic substrate;
forming a metal-containing layer conforming to a surface of the recess and to an adjacent surface of the substrate;
plasma treating the substrate having the metal-containing layer thereon; and
depositing aluminum on the metal-containing layer to form an aluminum layer thereon.

2. The method of claim 1, wherein depositing aluminum comprises depositing the aluminum at a temperature of about 160° C. or less.

3. The method of claim 1, wherein forming a recess comprises forming a contact hole in an insulating layer of the substrate that exposes an underlying conductive region of the substrate.

4. The method of claim 1, wherein the recess has an aspect ratio greater than about 1.

5. The method of claim 1, wherein forming a metal-containing layer comprises forming the metal-containing layer by metal organic chemical vapor deposition (MOCVD).

6. The method of claim 5, wherein the metal-containing layer is a barrier metal layer.

7. The method of claim 6, wherein the metal-containing layer comprises at least one material selected from a group consisting of titanium nitride (TiN), tantalum nitride (TaN), titanium silicon nitride (TiSiN) and tantalum silicon nitride (TaSiN).

8. The method of claim 1, wherein depositing aluminum comprises depositing aluminum on the metal-containing layer by chemical vapor deposition (CVD) using a methylpyrrolidine alane (MPA) source gas.

9. The method of claim 1, wherein plasma treating the substrate comprises plasma treating using at least one gas selected from a group consisting of argon (Ar), hydrogen (H₂), nitrogen (N₂), oxygen (O₂), nitrous oxide (N₂O) and ammonia (NH₃).

10. The method of claim 1, wherein plasma treating the substrate comprises plasma treating the substrate at a pressure in a range from about 1 Torr to about 6 Torr.

11. The method of claim 1, wherein plasma treating the substrate comprises plasma treating the substrate at a power level in a range from about 600 W to about 1,000 W.

12. The method of claim 1, wherein plasma treating the substrate comprises plasma treating the substrate for about 60 seconds.

13. The method of claim 1:
wherein forming a metal-containing layer is preceded by forming an ohmic layer conforming to an interior surface of the recess and to the adjacent surface of the insulating layer; and
wherein forming a metal-containing layer comprises forming the metal-containing layer on the ohmic layer.

14. The method of claim 13, wherein the ohmic layer comprises at least one of titanium (Ti) or tantalum (Ta).

15. The method of claim 1:
wherein forming a metal-containing layer comprises forming a first metal-containing layer;
wherein plasma treating comprises plasma treating the substrate having the first metal-containing layer thereon;
wherein depositing aluminum on the metal-containing layer comprises depositing aluminum on the first metal-containing layer to form a first aluminum layer thereon; and
wherein the method further comprises:
forming a second metal-containing layer conforming to an interior surface of the recess and to an adjacent surface of the insulating layer;
plasma treating the substrate having the second metal-containing layer thereon; and
depositing aluminum on the second metal-containing layer at a temperature of about 160° C. or less to form a second aluminum layer thereon.

16. The method of claim 1, wherein depositing aluminum comprises depositing aluminum by CVD until the recess is filled.

17. The method of claim 1, wherein depositing aluminum comprises:
depositing aluminum by CVD to form a seed aluminum layer in the recess; and
sputter depositing aluminum on the seed aluminum layer in the recess; and
wherein the method further comprises reflowing the deposited aluminum in the recess.

18. The method of claim 1, wherein plasma treating the substrate comprises plasma treating the substrate under conditions sufficient to cause aluminum to deposit at a greater rate on a portion of the metal-containing layer within the recess than on a portion of the metal-containing layer adjacent the recess.

19. The method of claim 1, wherein the recess comprises one of a hole, a trench, a groove or a step.

20. A method of forming an aluminum structure in a microelectronic article, the method comprising:
forming a recess in a microelectronic substrate;
forming a metal-containing layer that conforms to an inner surface of the recess and to a surface of the substrate adjacent the recess;
decreasing a carbon concentration in a portion of the metal-containing layer on the surface of the substrate adjacent the recess in comparison to a portion of the metal-containing layer within the recess; and
depositing aluminum on the metal-containing layer to form an aluminum layer that conforms to the inner surface of the recess and to the surface of the substrate adjacent the recess.

21. The method of claim 20, wherein decreasing a carbon concentration comprises plasma-treating the substrate having the metal-containing layer thereon.

22. The method of claim 21, wherein plasma treating the substrate comprises plasma treating the substrate with at least one gas selected from a group consisting of argon (Ar), hydrogen (H₂), nitrogen (N₂), oxygen (O₂), nitrous oxide (N₂O) and ammonia (NH₃) at a pressure in a range from about 1 Torr to about 6 Torr and a power level in a range from about 600 W to about 1,000 W.

23. The method of claim 21, wherein plasma treating the substrate comprises plasma treating the substrate with at least one gas selected from a group consisting of argon (Ar), hydrogen (H₂), nitrogen (N₂), oxygen (O₂), nitrous oxide (N₂O) and ammonia (NH₃) at a pressure in a range from about 1 Torr to about 6 Torr and a power level in a range from about 600 W to about 1,000 W for a duration of about 60 seconds.

24. The method of claim 20, wherein decreasing a carbon concentration in a portion of the metal-containing layer on the surface of the substrate adjacent the recess in comparison to a portion of the metal-containing layer within the recess comprises creating a difference in carbon concentration between the portion of the metal-containing layer on the surface of the substrate adjacent the recess and the portion of the metal-containing layer within the recess sufficient to cause aluminum to deposited at a greater rate on the portion of the metal-containing layer within the recess than on the portion of the metal-containing layer on the surface of the substrate adjacent the recess.

25. The method of claim 20, wherein forming a metal-containing layer comprises depositing a layer comprising at least one of Ta and Ti using a metal organic source gas.

26. The method of claim 20, wherein depositing aluminum comprises depositing aluminum on the metal-containing layer using a CVD process with an MPA source gas.

27. The method of claim 26, wherein depositing aluminum comprises depositing aluminum on the metal-containing layer using an MPA source gas at a temperature of about 160° C. or less.

28. The method of claim 20, wherein the recess comprises one of a hole, a trench, a groove or a step.

29. A microelectronic article of manufacture, comprising:
a substrate having a recess herein; and
a metal-containing layer on the substrate that conforms to an inner surface of the recess and to a surface of the substrate adjacent the recess, wherein the metal-containing layer has a substantially higher concentration of carbon in a portion of the metal-containing layer in the recess than in a portion of the metal-containing layer on the surface of the substrate adjacent the recess.

30. The microelectronic article of manufacture of claim 29, wherein the metal-containing layer comprises at least one of Ta and Ti.

31. The microelectronic article of manufacture according to claim 29, wherein the concentration of carbon in the portion of the metal-containing layer in the recess is sufficiently higher that the carbon concentration in the portion of the metal-containing layer on the surface of the substrate adjacent the recess to cause aluminum to deposit more rapidly on the portion of the metal-containing layer in the recess that on the portion of the metal-containing layer on the surface of the substrate adjacent the recess in an CVD process using an MPA source gas.
